(19) United States
(12) Patent Application Publication
(10) Pub. No.: US 2006/0158865 A1
(43) Pub. Date: Jul. 20, 2006

(54) Circuit board, electronic device employing circuit board, and mehtod of producing circuit board

(75) Inventors: Tadahiro Ohmi, Sendai-shi, Miyagi (JP); Shigetoshi Sugawa, Sendai-shi, Miyagi (JP); Akihiro Morimoto, Sendai-shi, Miyagi (JP); Takeyoshi Kato, Tokyo (JP)

Correspondence Address: BIRCH STEWART KOLASCH & BIRCH, PO BOX 747, FALLS CHURCH, VA, 22040-0747, US

(73) Assignee: Tadahiro OHMI, Tokyo (JP)

(21) Appl. No.: 10/525,329

(22) PCT Filed: Aug. 25, 2003
(86) PCT No.: PCT/JP03/10687

§ 371 Date: Nov. 2, 2005

(30) Foreign Application Priority Data
Aug. 23, 2002 (JP) 2002-244216
Aug. 8, 2003 (JP) 2003-290912

(51) Int. Cl. H05K 1/03; H05K 1/18

(52) U.S. Cl. 361/795; 174/258; 361/760

(57) ABSTRACT

A circuit board (100) having an insulator layer and a conductor (104) buried in the insulator layer, wherein the insulator layer has a first insulator (101) satisfying a relation μr≧εr, assuming εr is the dielectric constant and μr is the relative permeability, and the conductor is substantially surrounded by the first insulator.

### TECHNICAL FIELD

The present invention relates to a circuit board used as, for example, a high-frequency printed wiring board or the like and, more specifically, relates to a circuit board that consumes low current, has an excellent function of suppressing crosstalk and radiation noise, and can improve the quality of a signal propagating in a line. The present invention also relates to an electronic device employing the circuit board and a method of producing the circuit board.

### BACKGROUND ART

Microstrip lines, striplines, and so forth widely used as high-frequency signal transmission lines are formed on circuit boards such as printed wiring boards and used in various electronic devices such as portable telephones, personal computers, and household electric devices.

It is general that use is normally made of 50Ω as a characteristic impedance of the foregoing signal transmission line.

Further, in order to supply a sufficient signal to this 50Ω line from an active element such as an LSI (Large Scale Integrated) circuit, for example, a buffer circuit is formed at an input/output portion of the LSI circuit to drive the 50Ω line by producing a large current through the buffer circuit.

There has been a problem that since such a signal transmission line formed on the circuit board such as the printed wiring board generally has a low characteristic impedance of 50Ω, it is necessary to flow a large current for propagating a signal in the transmission line so that a buffer circuit increases in size and the power consumption increases.

For example, when propagating a signal of 1V in a transmission line, it is necessary to flow a current of I=V/Z=20 mA (I: current, V: voltage, Z: characteristic impedance) according to the Ohm's law. Particularly in portable devices such as portable telephones, there has arisen a serious problem that flowing a large current causes a reduction in battery life, and so forth.

As a technique for solving the foregoing problem, there is a technique of increasing the characteristic impedance of a transmission line to thereby reduce the current flowing in the transmission line. However, there has been a problem that the characteristic impedance of a normal transmission line has an upper limit of about 200 to 300Ω and therefore a sufficient power consumption reducing effect cannot be achieved.

The state of this will be explained using FIG. 1. FIG. 1 is a characteristic diagram showing a relationship between a line width W and a characteristic impedance Z in a microstrip line, wherein plotting is performed using as a parameter a relative permittivity εr of a dielectric having a thickness h=100 μm and interposed between a line and a ground metal layer. Note that a thickness t of the line is 10 μm.

As shown in FIG. 1, it is understood that although the characteristic impedance increases by reducing the line width W, it saturates at about 200Ω to 300Ω and stops increasing. The characteristic impedance (intrinsic impedance) Z, when an electromagnetic wave propagates in a uniform medium, is given as Z=(μ/ε)^{1/2} where μ represents the permeability of the foregoing medium and ε represents the permittivity of the foregoing medium. In the case of a general dielectric such as a resin, the relative permittivity ε is about 2 to 4 and the relative permeability μ is about 1, and therefore, a theoretical limit of the characteristic impedance is 267Ω when the relative permittivity is 2, while, it is 188Ω when the relative permittivity is 4. Even if a resin having a relative permittivity of 1 is realized, the theoretical limit of the characteristic impedance becomes 377Ω. Therefore, a limit has been placed upon the reduction of the power consumption by increasing the characteristic impedance simply on prolongation of the conventional technique.

To explain this using a relative permittivity εr and a relative permeability μr, since μr (about 1)<εr in a general dielectric that has conventionally been used, the intrinsic impedance never becomes greater than the intrinsic impedance (377Ω) in a vacuum.

Further, there has arisen a problem that crosstalk increases due to a reduction in distance between the adjacent lines formed on the printed wiring board, which is caused by reducing the size of the printed wiring board.

As described above, the electronic device such as the portable telephone, personal computer or household electric device comprises an LSI (Large Scale Integrated) circuit, peripheral components, and a circuit board for integrating and mutually connecting them.

In order to satisfy requests of various electronic circuits, the circuit board generally has a structure in which a plurality of wiring layers are formed via insulator layers.

The plurality of wiring layers are electrically connected to each other through electrical connection members that are formed, by a wiring plating process or the like, in connection holes called via holes or through holes formed in the insulator layers.

Such connection holes are generally formed by laser processing or drilling.

In the case of the laser processing, use is made of a carbon dioxide laser that emits light in an absorption wavelength band of a resin forming the insulator layers. By raising the temperature of a processing portion locally to 300° C. or higher to thermally decompose and evaporate the resin, the connection hole is formed.

As described above, the circuit board generally requires a multilayer wiring structure formed by electrically connecting the different wiring layers to each other by the use of the connection holes such as via holes or through holes.

Although the carbon dioxide laser has conventionally been mainly used in the processing of the connection holes, this method has caused a problem that since the hole is opened by thermally melting and evaporating the resin, the shape of an opening portion is extremely degraded.

### DISCLOSURE OF THE INVENTION

A first object of the present invention is to solve these problems and to increase the characteristic impedance of a signal transmission line, which has conventionally been about 200Ω as the upper limit, to 300Ω or more, preferably 500Ω or more, to thereby reduce the power consumption of the whole LSI system including a circuit board such as a printed wiring board. A second object of the present invention is to suppress crosstalk and radiation noise between adjacent lines to thereby improve the signal quality of signals propagating in the lines.

Further, a third object of the present invention is to provide a circuit board as a multilayer wiring board that is indispensable in an electronic device.

(A) For accomplishing the foregoing first and second objects, the present invention has the following structure.

Specifically, a circuit board according to the present invention is a circuit board in which a conductor (line) is buried inside an insulator layer and which is characterized in that the conductor (line) is substantially surrounded by a first insulator satisfying a relationship of μr≧εr given that a relative permittivity is εr and a relative permeability is μr (i.e. a magneto-dielectric having an intrinsic impedance Z of 377Ω or more). Since the conductor (line) is substantially surrounded by the first insulator (magneto-dielectric), a magnetic field generated around the conductor (line) can be confined within the first insulator (magneto-dielectric) surrounding the conductor (line). Therefore, it is possible to suppress crosstalk and radiation noise between the adjacent conductors (lines) to thereby improve the quality of signals propagating in the conductors (lines).

In the present invention, the conductor may be substantially surrounded by a second insulator not satisfying the relationship of μr≧εr and the second insulator may be substantially surrounded by the first insulator. Alternatively, at least a part of the conductor may be substantially surrounded by a second insulator not satisfying the relationship of μr≧εr and the second insulator along with the conductor may be substantially surrounded by the first insulator.

In the present invention, “insulator” represents one having a specific resistance equal to or greater than 1 kΩcm as measured by JISC3005. Further, in the present invention, “conductor” represents one having a specific resistance less than 1 kΩcm as measured by JISC3005 and is used as a concept including a line and a circuit. The shape of the conductor in section (section perpendicular to a longitudinal direction) is not limited to a rectangular shape and may be a circular shape, an oval shape, or another shape. Further, the sectional shape of the insulator is also not particularly limited.

Further, in the present invention, “substantially surrounded” means that even if there is a portion not surrounded, as long as the effective permeability and permittivity satisfy required values, it is sufficient.

In the present invention, the relative permittivity εr and the relative permeability μr of the insulator are evaluated by the effective permittivity and the effective permeability affecting an electromagnetic wave propagating in the conductor, regardless of the structure of the insulator surrounding the conductor. As a method of measuring the effective permittivity and the effective permeability, use can be made of a triplate-line resonator method or the like which actually measures an electromagnetic wave propagating in a line to thereby determine the permittivity and the permeability.

According to the circuit board of the present invention, since the first insulator satisfying μr≧εr is used as the insulating material between the conductors, the intrinsic impedance can be increased to about 377Ω or more. Therefore, as compared with the conventional circuit board using the insulating material exhibiting μr<εr, the consumption current can be largely reduced. Consequently, it is possible to reduce the power consumption of the whole LSI system including an LSI circuit or a printed wiring board.

In the present invention, preferably, a predetermined number N(N is an integer equal to or greater than 2) of conductors are buried inside the insulator layer, the predetermined number N of the conductors are substantially surrounded by a predetermined number N of first insulators, respectively, and the predetermined number N of the first insulators are partitioned therebetween by second insulators not satisfying the relationship of μr≧εr. That is, the first insulators substantially surrounding the respective conductors are partitioned by the second insulators not satisfying μr≧εr with respect to the respective conductors. In the case of this invention, magnetic fields generated around the conductors such as lines can be confined within the respective first insulators surrounding the conductors so that it is possible to suppress crosstalk and radiation noise between the adjacent conductors such as the lines to thereby improve the signal quality of signals propagating in the conductors such as the lines.

In the present invention, preferably, the first insulator is formed by mixing a magnetic substance into an inorganic substance. By mixing the magnetic substance (μr≧1) into the inorganic substance, the first insulator satisfying μr≧εr can be easily realized. As the inorganic substance, use can be made of ceramics such as silica, alumina, aluminum nitride, silicon nitride, or BST (bariumstrontium titanate), or SOG (Spin On Glass). An SOG liquid is adjusted based on a siloxane component which will be a film, an alcohol component as a solvent, and the like. By applying this solution to a substrate by a spin coat method and evaporating the solvent and so forth by a heat treatment to thereby cure a film, an SOG insulating film is formed. SOG is a general term of the solution and the film formed. SOG is classified, according to structures of siloxane, into silica glass, alkylsiloxane polymer, alkylsilsesquioxane polymer (MSQ), hydrogen silsesquioxane polymer (HSQ), and hydrogen alkylsilsesquioxane polymer (HOSP). When classified according to application materials, the silica glass is the first-generation inorganic SOG, the alkylsiloxane polymer is the first-generation organic SOG, HSQ is the second-generation inorganic SOG, and MSQ and HOSP are the second-generation organic SOG. Silica, alumina, or the like may be formed into a film by simultaneous sputtering with a magnetic material according to a cosputtering method, or powder thereof and magnetic material powder may be kneaded into paste to form a green sheet which is then dried and sintered, thereby obtaining the first insulator. This also applies to the case where a ceramics material is used.

Alternatively, in the present invention, the first insulator may be formed by containing a synthetic resin and a magnetic substance. Also in this case, by mixing the magnetic substance (μr>1) into the synthetic resin, the first insulator satisfying μr≧εr can be easily realized.

The first insulator may also contain, in addition to the magnetic substance and the synthetic resin, a curing agent, curing accelerator, flame retarder, soft polymer, heat resistant stabilizer, weather resistant stabilizer, age resistor, leveling agent, antistatic agent, slip agent, antiblocking agent, defogging agent, lubricant, dye, pigment, natural oil, synthetic oil, wax, emulsion, filler, ultraviolet absorbent, or the like.

In the present invention, the synthetic resin is not particularly limited, but may be exemplified by, for example, an epoxy resin, phenol resin, polyimide resin, polyester resin, fluorine resin, denatured polyphenylether resin, bismaleimide triazine resin, denatured polyphenylene oxide resin, silicon resin, benzocyclobutene resin, polyethylene naphthalate resin, polycycloolefin resin, polyolefin resin, fluorocarbon polymer, cyanate ester resin, melamine resin, or acrylic resin.

Since these resins each have a lower permittivity as compared with a ferrite-based material being a typical magnetic material, it is possible to exhibit an impedance increasing effect without canceling a permeability increasing effect. Such a resin is preferable that exhibits a small dielectric loss (tanδ) and contains small amounts of water and unnecessary organic substance. The polycycloolefin resin, the polyolefin resin, or the fluorocarbon polymer, with the relative permittivity being about 2 to 3 and tanδ=2×10⁻⁴, is particularly preferable.

In the present invention, it is preferable that the magnetic substance be uniformly dispersed as fine particles (powder) in the foregoing inorganic substance or resin. The magnetic substance may be electrically insulative or conductive. The electrically insulative magnetic substance is not particularly limited, but may be exemplified by a metal oxide magnetic substance containing Co, Ni, Mn, Zn, or the like. By adding the insulative magnetic substance, an eddy-current loss in the first insulator constituting the circuit board becomes ignorably small, and it exclusively contributes to increasing the permeability of the circuit board. Since the eddy-current loss of the circuit board can be reduced, it is possible to suppress the loss even at high frequencies of about several hundreds of MHz to 1 GHz. The conductive magnetic substance may be exemplified by powder of a simple substance or an alloy of magnetic metal elements such as Fe, Ni, Co, or Cr. Since the powder of the simple substance or the alloy of the magnetic metal elements is dispersed in the foregoing inorganic substance or resin, the electrical insulation property of the first insulator is ensured on the whole.

In the present invention, the amount of the magnetic substance relative to 100 weight parts of the synthetic resin is not particularly limited, but it is normally contained in the first insulator at the rate of 1/10⁶ to 300 weight parts. By setting the rate of the content of the magnetic substance to such a range, the operation and effect of the present invention is enhanced. If the content rate of the magnetic substance is too low, the amount of the magnetic substance existing in the first insulator decreases so that the operation and effect of the present invention is lowered. Conversely, if it is too high, difficulty tends to occur in terms of production, for example, uniform dispersibility cannot be achieved.

As described above, according to the present invention, it is possible to increase the characteristic impedance of the signal transmission line, which has conventionally been about 200% as the upper limit, to 300Ω or more, preferably 500Ω or more, to thereby reduce the power consumption of the whole LSI system including the circuit board such as the printed wiring board. Further, according to the present invention, it is possible to suppress crosstalk and radiation noise between the adjacent lines to thereby improve the signal quality of signals propagating in the lines.

(B) According to the present invention, a circuit board as a multilayer wiring board indispensable in an electronic device for accomplishing the foregoing third object is as follows. Further, according to the present invention, an electronic device employing such a circuit board and a method of producing such a circuit board are as follows.

(1) A circuit board characterized by comprising an insulator layer having mutually opposing first and second main surfaces, and a first and a second wiring layer formed on the first and second main surfaces of the insulator layer, wherein at least a part of the insulator layer satisfies a relationship of εr≦μr given that a relative permittivity of the insulator layer is εr and a relative permeability thereof is μr.

(2) An electronic device characterized by comprising a circuit board which comprises an insulator layer having mutually opposing first and second main surfaces, and a first and a second wiring layer formed on the first and second main surfaces of the insulator layer, wherein at least a part of the insulator layer satisfies a relationship of εr≦μr given that a relative permittivity of the insulator layer is εr and a relative permeability thereof is μr.

(3) An electronic device according to the foregoing item (2), characterized by comprising a battery and receiving a power supply from the battery to operate.

(4) An electronic device according to the foregoing item (2), characterized by comprising a battery and being adapted to operate by receiving a power supply from the battery without receiving a power supply from a commercial power supply.

(5) An electronic device according to any of the foregoing items (2) to (4), characterized in that the electronic device is a portable telephone.

(6) An electronic device according to any of the foregoing items (2) to (4), characterized in that the electronic device is a personal computer.

(7) A method of producing a circuit board comprising an insulator layer having a hole, wherein at least a part of the insulator layer satisfies a relationship of εr≦μr given that a relative permittivity of the insulator layer is εr and a relative permeability thereof is μr, the method characterized by comprising:

a step of performing ultrasonic cleaning of the inside of the hole by the use of ozone-containing acid pure water in which pH is adjusted to an acid region by adding O₃ and CO₂ into pure water; and

a step of performing ultrasonic cleaning by the use of hydrogen-containing alkaline pure water in which pH is adjusted to an alkaline region by adding H₂ and NH₃ into pure water.

(8) A method of producing a circuit board comprising an insulator layer having a hole, wherein at least a part of the insulator layer satisfies a relationship of εr≦μr given that a relative permittivity of the insulator layer is εr and a relative permeability thereof is μr, the method characterized by comprising:

a step of forming the hole in the insulator layer by the use of a laser beam having a wavelength of 400 nm or less, or 700 nm or more.

(9) A circuit board characterized by comprising an insulator layer having mutually opposing first and second main surfaces and a hole perpendicular to the first and second main surfaces, and a first and a second wiring layer formed on the first and second main surfaces of the insulator layer, wherein at least a part of the insulator layer satisfies a relationship of εr≦μr given that a relative permittivity of the insulator layer is εr and a relative permeability thereof is μr, the circuit board further comprising an electrical connection member formed on an inner surface of the hole so as to contact the first and second wiring layers for electrically connecting between the first and second wiring layers.

(10) An electronic device characterized by comprising a circuit board which comprises an insulator layer having mutually opposing first and second main surfaces and a hole perpendicular to the first and second main surfaces, and a first and a second wiring layer formed on the first and second main surfaces of the insulator layer, wherein at least a part of the insulator layer satisfies a relationship of εr≦μr given that a relative permittivity of the insulator layer is εr and a relative permeability thereof is μr, the circuit board further comprising an electrical connection member formed on an inner surface of the hole so as to contact the first and second wiring layers for electrically connecting between the first and second wiring layers.

(11) An electronic device according to the foregoing item (10), characterized by comprising a battery and receiving a power supply from the battery to operate.

(12) An electronic device according to the foregoing item (10), characterized by comprising a battery and being adapted to operate by receiving a power supply from the battery without receiving a power supply from a commercial power supply.

(13) An electronic device according to any of the foregoing items (10) to (12), characterized in that the electronic device is a portable telephone.

(14) An electronic device according to any of the foregoing items (10) to (12), characterized in that the electronic device is a personal computer.

Hereinafter, an insulator satisfying the relationship of εr≦μr will be referred to as a magneto-dielectric or a magneto-dielectric portion.

In the present invention, since a circuit board using a magneto-dielectric can be formed in multilayers, various electronic devices can be configured to achieve low power consumption. By using the magneto-dielectric for a part of wiring layers, leakage of a magnetic field from the inside of the magneto-dielectric is reduced so that it is possible to reduce crosstalk between the wiring layers while maintaining low power consumption.

### BRIEF DESCRIPTION OF THE DRAWINGS

FIG. 1 is a characteristic diagram showing a relationship between a line width and a characteristic impedance of a conventional microstrip line.

FIG. 2 is a sectional view showing a structure of a printed wiring board of the present invention.

FIGS. 3A to 3D are sectional views showing a production method of a printed wiring board of the present invention.

FIG. 4 is a sectional view showing a structure of the printed wiring board obtained by the production method of FIG. 3.

FIG. 5 is a sectional view showing a structure of a printed wiring board of the present invention.

FIG. 6 is a sectional view showing a structure of a printed wiring board of the present invention.

FIGS. 7A and 7B are sectional views showing structures of printed wiring boards of the present invention, respectively.

FIG. 8 is a sectional view showing a structure of a printed wiring board of the present invention.

FIG. 9 is a sectional view showing a structure of a printed wiring board of the present invention.

FIG. 10 is a sectional view showing a structure of a printed wiring board of the present invention.

FIG. 11 is a sectional view showing a structure of a printed wiring board of the present invention.

FIG. 12 is a sectional view showing a structure of a printed wiring board of the present invention.

FIGS. 13A to 13C are sectional views showing production processes of the printed wiring board of FIG. 11.

FIG. 14 is a characteristic diagram showing relationships between the characteristic impedance and the line width when striplines are formed in printed wiring boards in a specific example of the present invention and a comparative example.

FIG. 15 is a characteristic diagram showing a relationship between the characteristic impedance and the relative permeability when a stripline is formed in a printed wiring board in a specific example of the present invention.

FIG. 16 is a characteristic diagram showing a relationship among the characteristic impedance of a transmission line formed in a printed wiring board using a first insulator in a specific example of the present invention, the power consumption, and the frequency.

FIG. 17 is a sectional view showing one step of a production process of a multilayer circuit board using a magneto-dielectric, according to a first embodiment of the present invention.

FIG. 18 is a sectional view showing one step of the production process of the multilayer circuit board using the magneto-dielectric, according to the first embodiment of the present invention.

FIG. 19 is a sectional view showing one step of the production process of the multilayer circuit board using the magneto-dielectric, according to the first embodiment of the present invention.

FIG. 20 is a sectional view showing one step of the production process of the multilayer circuit board using the magneto-dielectric, according to the first embodiment of the present invention.

FIG. 21 is a sectional view showing one step of the production process of the multilayer circuit board using the magneto-dielectric, according to the first embodiment of the present invention.

FIG. 22 is a sectional view showing one step of the production process of the multilayer circuit board using the magneto-dielectric, according to the first embodiment of the present invention.

FIG. 23 is a sectional view showing one step of the production process of the multilayer circuit board using the magneto-dielectric, according to the first embodiment of the present invention.

FIG. 24 is a sectional view showing one step of the production process of the multilayer circuit board using the magneto-dielectric, according to the first embodiment of the present invention.

FIG. 25 is a sectional view showing one step of the production process of the multilayer circuit board using the magneto-dielectric, according to the first embodiment of the present invention.

FIG. 26 is a sectional view showing one step of the production process of the multilayer circuit board using the magneto-dielectric, according to the first embodiment of the present invention.

FIG. 27 is a sectional view of the multilayer circuit board using the magneto-dielectric, according to the first embodiment of the present invention.

FIG. 28 is a sectional view of a multilayer circuit board using a magneto-dielectric, according to a second embodiment of the present invention.

FIG. 29 is a sectional view showing one step of a production process of a multilayer circuit board using a magneto-dielectric, according to a third embodiment of the present invention.

FIG. 30 is a sectional view showing one step of the production process of the multilayer circuit board using the magneto-dielectric, according to the third embodiment of the present invention.

FIG. 31 is a sectional view showing one step of the production process of the multilayer circuit board using the magneto-dielectric, according to the third embodiment of the present invention.

FIG. 32 is a sectional view showing one step of the production process of the multilayer circuit board using the magneto-dielectric, according to the third embodiment of the present invention.

FIG. 33 is a sectional view showing one step of the production process of the multilayer circuit board using the magneto-dielectric, according to the third embodiment of the present invention.

FIG. 34 is a sectional view showing one step of the production process of the multilayer circuit board using the magneto-dielectric, according to the third embodiment of the present invention.

FIG. 35 is a sectional view showing one step of the production process of the multilayer circuit board using the magneto-dielectric, according to the third embodiment of the present invention.

FIG. 36 is a sectional view of the multilayer circuit board using the magneto-dielectric, according to the third embodiment of the present invention.

FIGS. 37A and 37B are photographs used for explaining one step of a production process of a multilayer circuit board using a magneto-dielectric, according to a fourth embodiment of the present invention.

FIG. 38 is a diagram showing a portable telephone as an electronic device having the multilayer circuit board according to the embodiment of the present invention.

FIG. 39 is a diagram showing a personal computer (PC) as an electronic device having the multilayer circuit board according to the embodiment of the present invention.

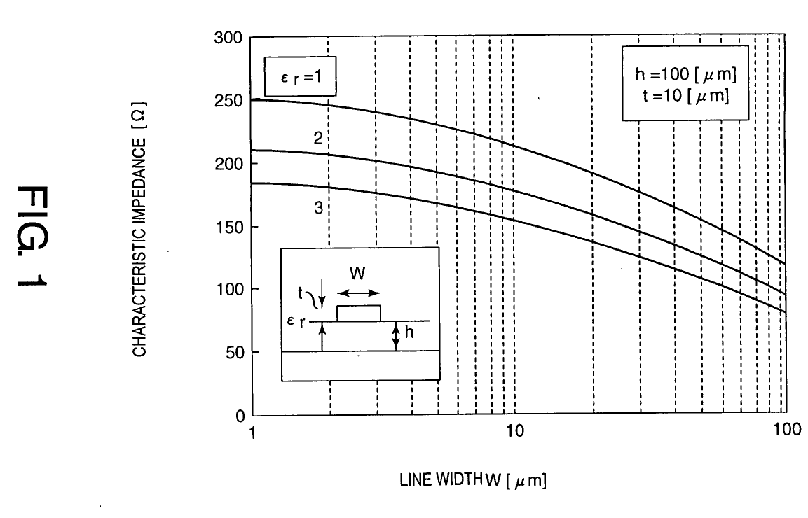

### BEST MODE FOR CARRYING OUT THE INVENTION

(A) Now, printed wiring boards of the present invention will be described based on embodiments shown in the drawings.

### First Embodiment (Printed Wiring Board)

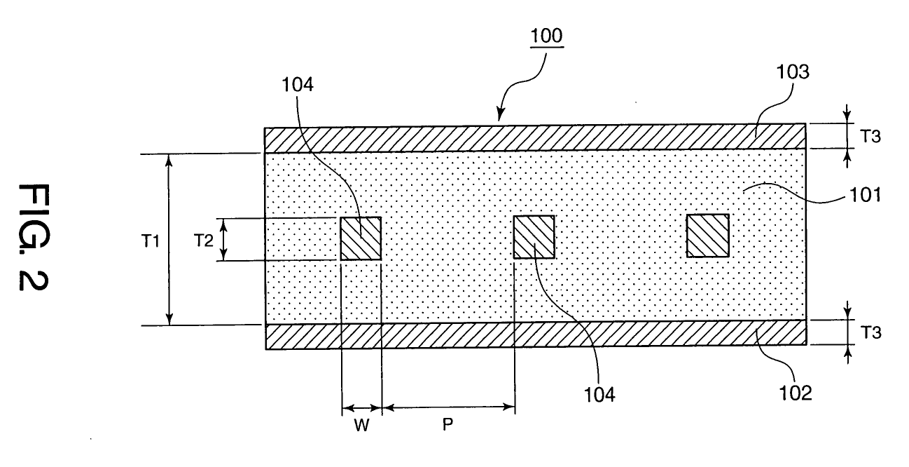

As shown in FIG. 2, a printed wiring board 100 as a circuit board according to one embodiment of the present invention comprises an insulator layer having a first insulator 101, and lines (conductors) 104 buried inside the insulator layer.

Specifically, the printed wiring board 100 comprises the first insulator 101 in the shape of a plate or a film, a first conductive film 102 formed on a lower surface of the first insulator 101, a second conductive film 103 formed on an upper surface of the first insulator 101, and the plurality of lines (conductors) 104 enclosed in the first insulator 101. The wiring board 100 of this embodiment is used as, for example, a board for a stripline.

A thickness T2 of each line 104 is not particularly limited but, when the wiring board 100 is used as a stripline, it is preferable that, given that the signal frequency is f, the conductivity of the line 104 is σ, and the permeability of the line 104 is μi, the thickness T2 be equal to or greater than a skin depth {1/(πfμiσ)}^{1/2} of penetration of an electromagnetic wave. A thickness T1 of the first insulator 101 surrounding the lines 104 is not particularly limited, but it is preferable that T′≧{1/(πfμiσ)}^{1/2} where T′ represents a smaller one of a distance a between the line 104 and the first conductive film 102 and a distance b between the line 104 and the second conductive film 103. With this configuration, the signal energy can be concentrated within the insulator so that loss in the lines can be reduced. Preferably, each line 104 is located at substantially a center portion, in the thickness direction, of the first insulator 101.

A width W of each line 104 is not particularly limited, but is preferably equal to or greater than {1/(πfμiσ)}^{1/2}. Distances P between the adjacent lines 104 may be equal or unequal to each other and are not particularly limited, each of which, however, is preferably an interval equal to or greater than T′ referred to above. With this configuration, it is possible to reduce crosstalk between the adjacent lines. Note that the number of the lines 104 buried inside the first insulator 101 is not particularly limited, and further, the lines 104 may be formed in the first insulator 101 in layers in the thickness direction thereof, and circuit boards each composed of 101, 102, 103, and 104 may be formed in layers.

A thickness T3 of each of the conductive films 102 and 103 formed on both surfaces of the first insulator 101 is not particularly limited, but is preferably equal to or greater than {1/(πfμiσ)}^{1/2}.

The first insulator 101 is obtained by mixing fine magnetic powder into a synthetic resin with a low permittivity. The fine magnetic powder has a size that is sufficiently smaller than a size of magnetic domain and is, for example, about several tens of nm or less. The magnetic powder is an insulator and is obtained by forming a metal oxide magnetic substance containing, for example, Co, Ni, Mn, Zn, or the like into a globular shape, a flat shape, or a fiber shape having a size of about several tens of nm or less which is smaller than the size of magnetic domain, by the use of an in-gas evaporation method, an atomization method, a chemical synthesis method, or the like. Alternatively, the magnetic powder may be obtained by forming fine powder of a metal magnetic substance and applying an oxidation treatment thereto.

The fine magnetic powder obtained as described above is mixed into the synthetic resin and molded to thereby obtain the first insulator 101 shown in FIG. 2. As a synthetic resin material, there is no particular limitation and the one exemplified above can be cited.

In general, the magnetic substance reduces its permeability as the frequency increases, by the Stokes limit. Therefore, when using the circuit board of this embodiment in a high-frequency manner, the first insulator 101 preferably has as low permittivity as possible. The synthetic resin has a lower permittivity as compared with a ferrite material or the like which is a typical magnetic material and thus can exhibit an intrinsic impedance increasing effect even in a high-frequency region. From this aspect, as the preferable synthetic resin, the polycycloolefin resin or the polyolefin resin as described above is particularly preferable.

A material of the conductive films 102 and 103 and the lines 104 is not particularly limited as long as it is a conductive material, and use is made of an ordinary wiring material such as a material containing, as a main component, a metal material, for example, copper, gold, silver, aluminum, or the like.

The lines 104 are buried inside the first insulator 101, for example, in the following manner.

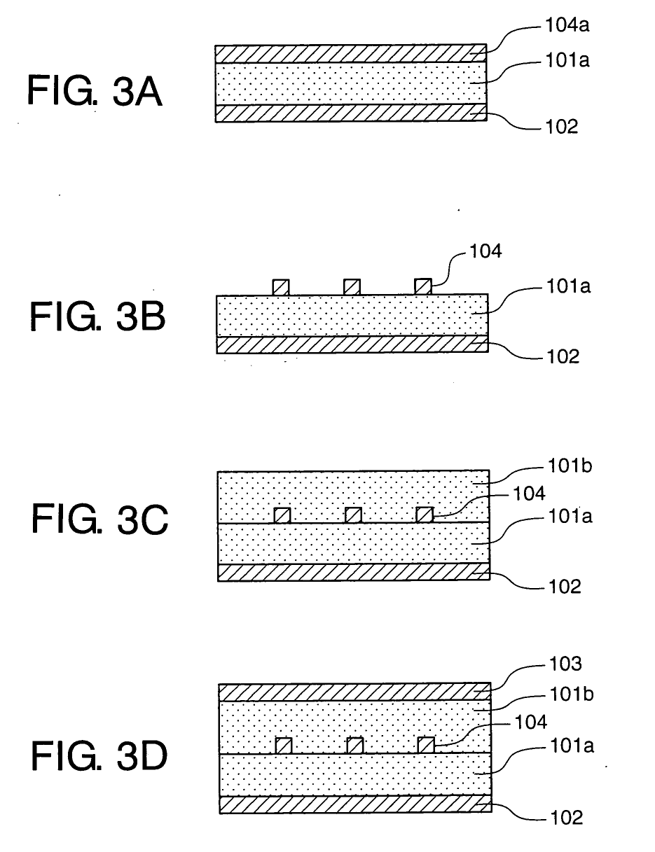

As shown in FIG. 3A, at the outset, a lower insulating layer 101a of the first insulator 101 is formed in the shape of a sheet. A first conductive film 102 is formed on a lower surface of the lower insulating layer 101a and a wiring layer 104a is formed on an upper surface of the lower insulating layer 101a. The first conductive film 102 and the wiring layer 104a each can be obtained by, for example, forming a Cu film by a plating method, a sputtering method, an organic metal CVD method, a bonding method of a metal film such as Cu, or the like.

Then, as shown in FIG. 3B, the wiring layer 104a is patterned by a photolithography method or the like to thereby form lines 104 in a desired pattern. Subsequently, as shown in FIG. 3C, an upper insulating layer 101b is stacked on the lower insulating layer 101a formed with the lines 104. The upper insulating layer 101b is formed in the shape of a sheet like, for example, the lower insulating layer 101a and stuck onto the lower insulating layer 101a by, for example, a press method. Thereafter, as shown in FIG. 3D, a second conductive film 103 is formed on the upper insulating layer 101b like the first conductive film 102.

The upper insulating layer 101b may be formed by, for example, a spin coat method, an application method, or the like. For example, a solution obtained by putting a resin material into a solvent such as xylene and uniformly dispersing a fine magnetic material such as ferrite therein by a surface active agent or the like may be applied onto the lower insulating layer 101a by the spin coat method or the like, then burned to evaporate the solvent so as to be solidified, thereby forming the upper insulating layer 101b.

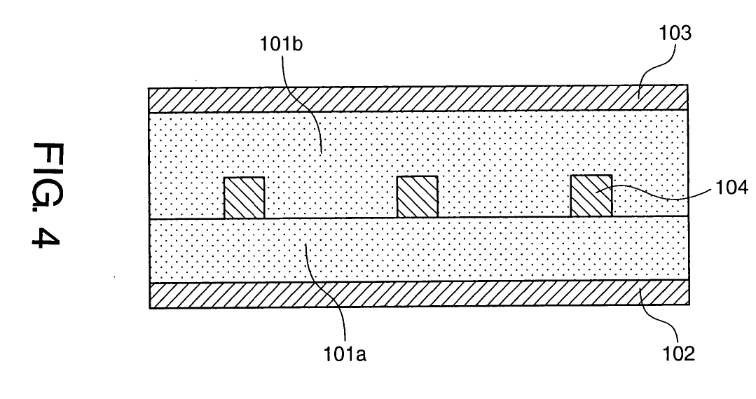

In the circuit board thus obtained, as shown in FIG. 4, the first insulator 101 is formed by the lower insulating layer 101a and the upper insulating layer 101b. The lower insulating layer 101a and the upper insulating layer 101b may be made of the same material or different materials. However, it is preferable that these insulating layers 101a and 101b both satisfy μr≧εr.

Further, at least one of the insulating layers may be formed by mixing a fine magnetic material into an inorganic substance such as a hydrogen silsesquioxane polymer (HSQ) of inorganic SOG (Spin On Glass) used in the production process of an LSI and applying and burning the mixture.

According to the wiring board 100 of this embodiment, since the first insulator 101 satisfying μr≧εr is used as the insulating material between the conductors, the intrinsic impedance can be increased to about 377Ω or more, preferably 300Ω or more, and further to 500Ω or more. This makes it possible to reduce the power consumption of the whole LSI system including the circuit board such as the printed wiring board.

Further, in this embodiment, since the lines 104 are buried in the first insulator 101, magnetic fields generated around the lines 104 can be confined within the first insulator 101 surrounding the lines so that it is possible to suppress crosstalk and radiation noise between the adjacent lines 104 to thereby improve the signal quality of signals propagating in the lines 104.

### Second Embodiment (Printed Wiring Board)

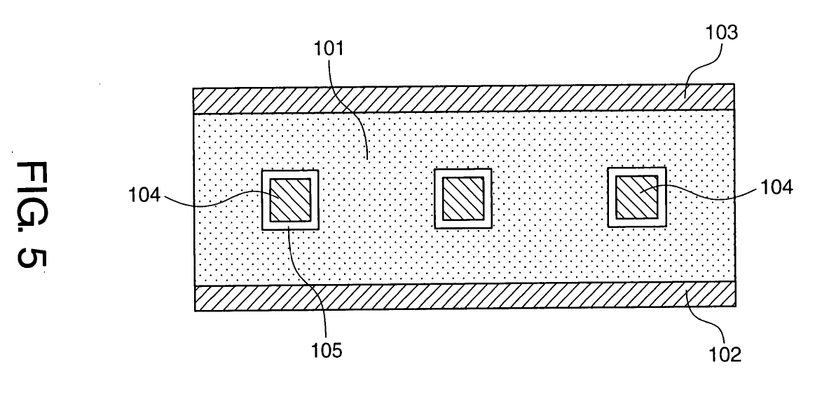

As shown in FIG. 5, this embodiment has the same structure as the foregoing first embodiment except that each of lines 104 is surrounded by a second insulator 105, and further, the second insulators 105 are surrounded by a first insulator 101, and similar operation and effect can be expected.

Hereinbelow, in each embodiment, those members common to the foregoing first embodiment will be assigned the same symbols to thereby omit a part of description thereof. Hereinbelow, description will be given in detail about only different points.

In this embodiment, the second insulator 105 surrounding the line 104 is made of an ordinary synthetic resin containing no fine magnetic material. In this second insulator 105, μr<εr and therefore μr≧εr is not satisfied. The thickness of the second insulator 105 may be optional as long as it is smaller than ½ of the distance P between the adjacent lines 104 shown in FIG. 2, and is preferably equal to or less than ⅓ of the distance P.

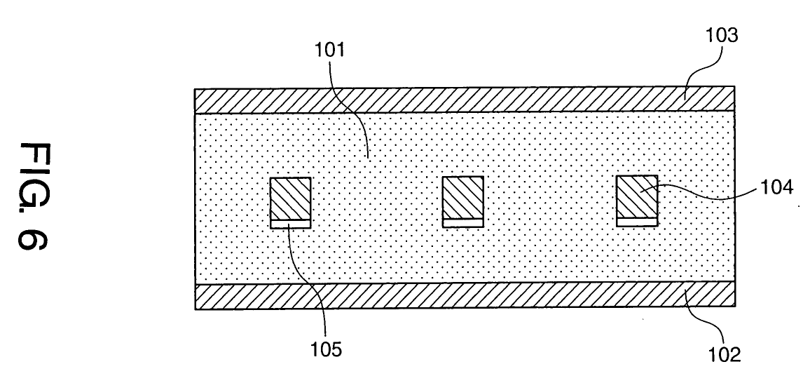

As shown in FIG. 6, the second insulator 105 does not necessarily cover the whole periphery of the line 104, but may cover only a part of the line 104.

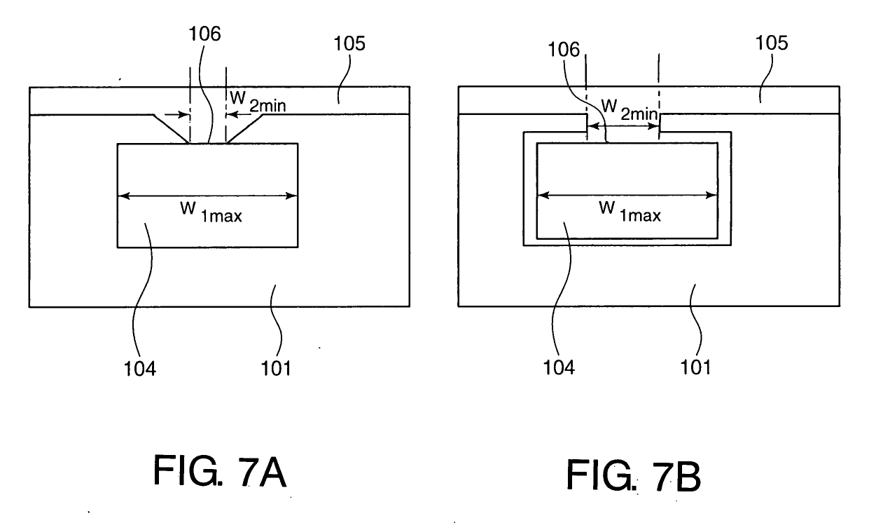

Further, as shown in FIG. 7A, it may be configured that a first insulator 101 does not cover the whole periphery of a line 104 and a portion 106 of the line 104 is surrounded by a second insulator 105. On the other hand, as shown in FIG. 7B, it may be configured that a first insulator 101 surrounds except a portion 106 of a line 104 in the state where a second insulator 105 is sandwiched between the first insulator 101 and the line 104, and the portion 106 of the line 104 is surrounded by the second insulator 105. Further, the line 104 may have a portion not surrounded by the first insulator 101 at an output port of the line 104 such as a through hole connection portion. As shown in FIGS. 7A and 7B, it is preferable that a width W2min of the portion 106 not surrounded by the first insulator 101 on the periphery of the line 104 be set narrower than a maximum width W1max of the line 104 in a direction parallel to the width W2min.

### Third Embodiment (Printed Wiring Board)

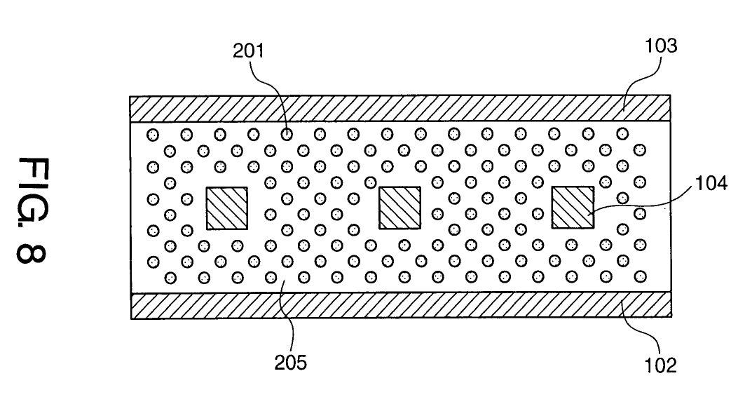

As shown in FIG. 8, this embodiment has the same structure as the foregoing first embodiment except that lines 104 are surrounded by a first insulator 205 in which globular first insulators 201 (different from the first insulator 101 only in shape) are dispersed, and similar operation and effect can be expected.

In this embodiment, the lines 104 are surrounded by the first insulator 205 having the globular first insulators 201 dispersed therein, which represents that each line (conductor) 104 is substantially surrounded by the first insulators 201.

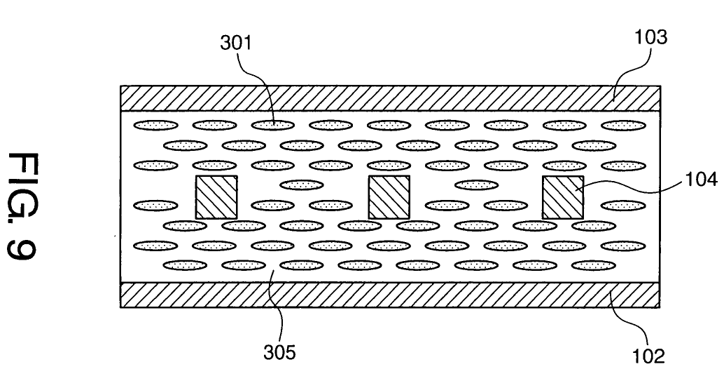

In the embodiment shown in FIG. 9, lines 104 are surrounded by a first insulator 305 having flat first insulators 301 dispersed therein, which represents that each line (conductor) 104 is substantially surrounded by the first insulators 301.

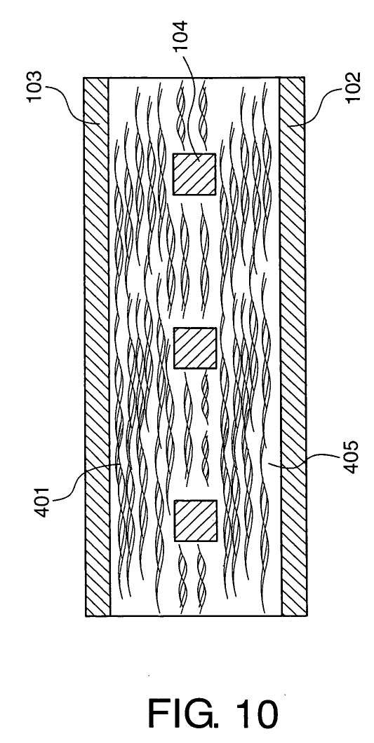

Further, in the embodiment shown in FIG. 10, lines 104 are surrounded by a first insulator 405 having fiber-shaped first insulators 401 dispersed therein, which represents that each line (conductor) 104 is substantially surrounded by the first insulators 401.

### Fourth Embodiment (Printed Wiring Board)

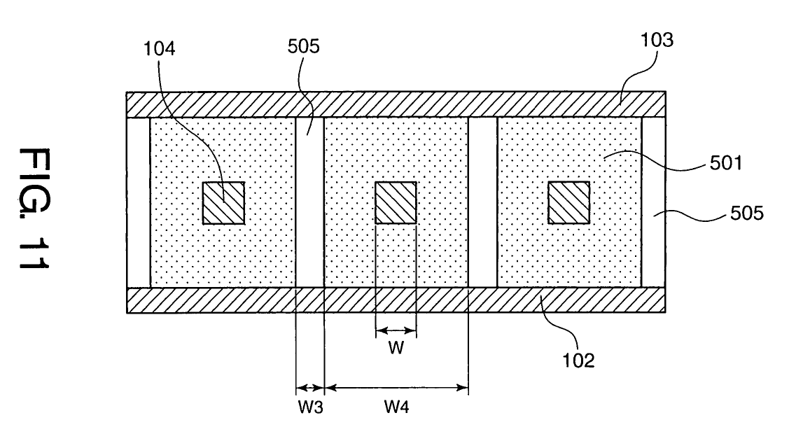

As shown in FIG. 11, in this embodiment, a first insulator 501 of a plate or film shape satisfying μr≧εr and formed between a first conductive film 102 and a second conductive film 103 is partitioned into first insulators 501 for respective lines 104 by second insulators 505 not satisfying μr≧εr.

The first insulator 501 is made of the same material and produced in the same manner as the first insulator 101 in the wiring board 100 of the foregoing first embodiment. The second insulator 505 is made of an ordinary synthetic resin and has no magnetic powder dispersed therein.

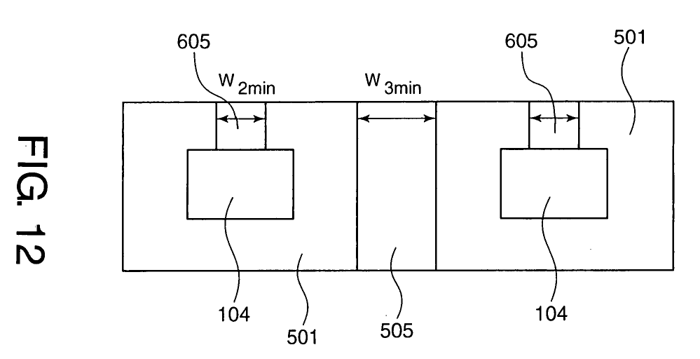

A width W4 of each insulator 501 is required to be greater than a width W of the line 104, wherein it is sufficient that the line 104 is substantially surrounded by the first insulator 501. The line 104 is preferably located substantially near the center of the first insulator 501 in the width direction thereof. A width W3 of each second insulator 505 may be smaller than the width W4 and is specifically greater than zero, and is determined so that the line 104 is substantially surrounded by the first insulator 501. Specifically, as shown in FIG. 12, a minimum width W3min of the second insulator 505 is required to be equal to or greater than a minimum width W2min of a portion 605 (the same material as the second insulator 505) where the line 104 is not surrounded by the first insulator 501.

The wiring board formed by alternately repeating the first insulators 501 and the second insulators 505 can be produced, for example, in the following manner.

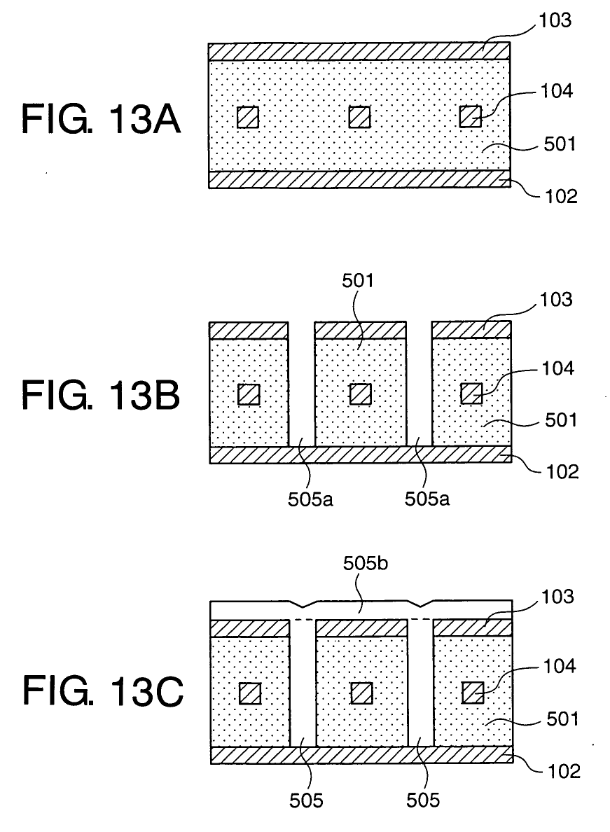

Specifically, at the outset, as shown in FIG. 13A, like in the process shown in FIG. 4, a board is formed in which lines 104 are buried inside a first insulator 501. Then, as shown in FIG. 13B, grooves 505a are formed, by laser processing or the like, in a pattern designed to form the second insulators 505 shown in FIG. 11. Thereafter, as shown in FIG. 13C, a resin, which will be the second insulators 505, is poured from above the grooves 505a by the spin coat method or the like to thereby form an insulator composed of the second insulators 505 and a portion 505b. Then, the unnecessary insulator portion 505b is removed.

According to the wiring board of this embodiment, the line 104 is buried in each first insulator 501, and further, the respective first insulators 501 are partitioned by the second insulators 505. Therefore, according to this embodiment, the operation and effect of the foregoing first embodiment can be further enhanced. Specifically, according to this embodiment, magnetic fields generated around the lines 104 can be confined further effectively within the first insulators 501 surrounding the lines 104, respectively, so that it is possible to suppress crosstalk and radiation noise between the adjacent lines 104 to thereby improve the signal quality of signals propagating in the lines 104.

The present invention is not limited to the foregoing embodiments and can be changed in various ways within the scope of the present invention.

For example, the circuit board according to the present invention can also be used as other than a board for a circuit other than the stripline, for example, a microstrip line or another circuit.

### Specific Example

Hereinbelow, the present invention will be described based on further detailed specific examples, but the present invention is not limited to these specific examples.

### Specific Example 1

A ferrite material (produced by Toda Kogyo Corporation) in the form of fine magnetic powder formed by insulators was uniformly dispersed into a wax obtained by dissolving, into a solvent, 100 parts of a polycycloolefin resin (denatured ring-opened polymer of norbornene-type cycloolefin (Tg=170° C.)), 40 parts of a bisphenol-based curing agent, and 0.1 parts of an imidazole-based effect accelerator, then, after casting, a heat treatment was applied thereto, thereby obtaining a first insulator 101 having a thickness T1=100 μm shown in FIG. 2. A relative permittivity ε of this first insulator 101 was 2.9. The ratio of a dispersion amount of the magnetic powder was 100 weight parts relative to 100 weight parts of the components of the wax other than the solvent.

Note that lines 104 formed by a copper metal and each having a sectional width W of 10 μm and a sectional thickness T2 of 10 μm were buried inside the first insulator 101 so as to be arranged at a wiring interval P=200 μm substantially at the center of the first insulator 101 in the thickness direction thereof.

Then, copper plating was applied to a lower surface and an upper surface of the first insulator 101 to form conductive films 102 and 103 each having a thickness of 20 μm, thereby obtaining a wiring board 100.

A permeability μ of the first insulator 101 in the wiring board 100 was measured to be 25.

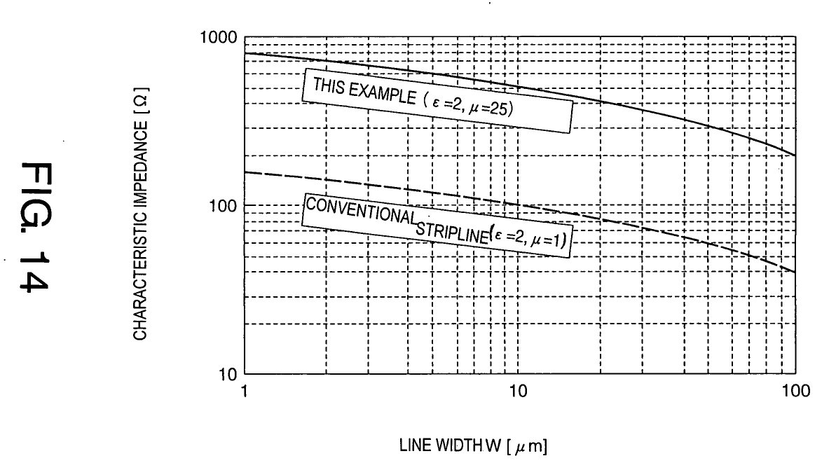

The width W of the line 104 was changed between 1 to 100 μm to derive a relationship with the characteristic impedance, and the result thereof is shown in FIG. 14 in solid line.

### Comparative Example 1

A wiring board was produced in the same manner as the forgoing Specific Example 1 except that an insulator was obtained instead of the first insulator 101 without dispersing the fine magnetic powder into the foregoing wax. A relative permittivity ε of the insulator was 2 and a permeability μ of the wiring board was 1. A width W of a line 104 was changed between 1 to 100 μm to derive a relationship with the characteristic impedance, and the result thereof is shown in FIG. 14 in dotted line.

### Evaluation 1

As shown in FIG. 14, it has been confirmed that the characteristic impedance is improved in the specific example of the present invention as compared with the comparative example (conventional stripline). Specifically, it has been confirmed that the characteristic impedance having the limit of 100 to 200Ω conventionally can be increased to about 300 to 500Ω or more in the specific example. Further, since it is not necessary to extremely narrow the line width for increasing the line impedance, it is possible to reduce loss caused by the line resistance.

### Specific Example 2

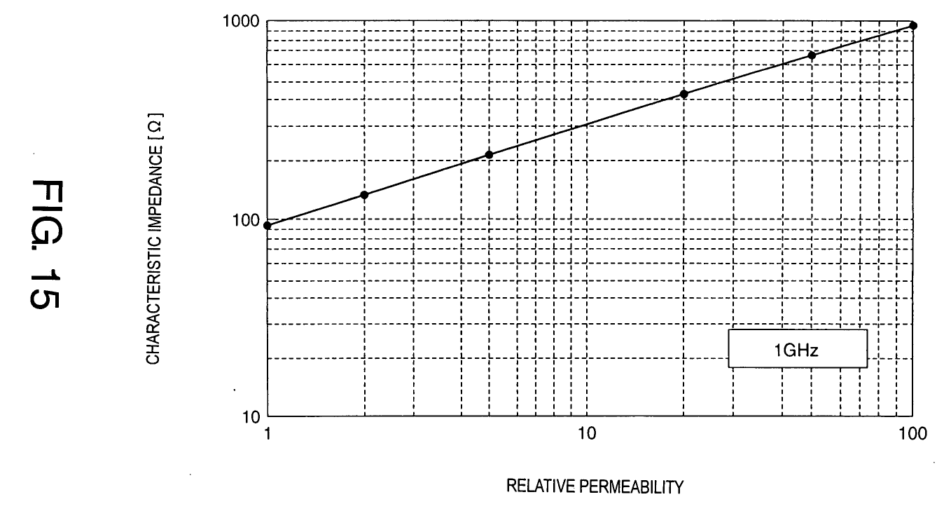

A wiring board was produced in the same manner as Specific Example 1 except that the dispersion amount of the magnetic powder in the first insulator 101 was changed and the permeability of the first insulator 101 at 100 MHz was changed in the range of 1 to 100. A relationship between the characteristic impedance of a transmission line formed in the wiring board 100 and the relative permeability of the first insulator 101 is shown in FIG. 15. It has been confirmed that it is possible to obtain a transmission line having a characteristic impedance of 500Ω with a relative permeability of about 25 and a characteristic impedance of 1000Ω with a relative permeability of about 100.

### Specific Example 3

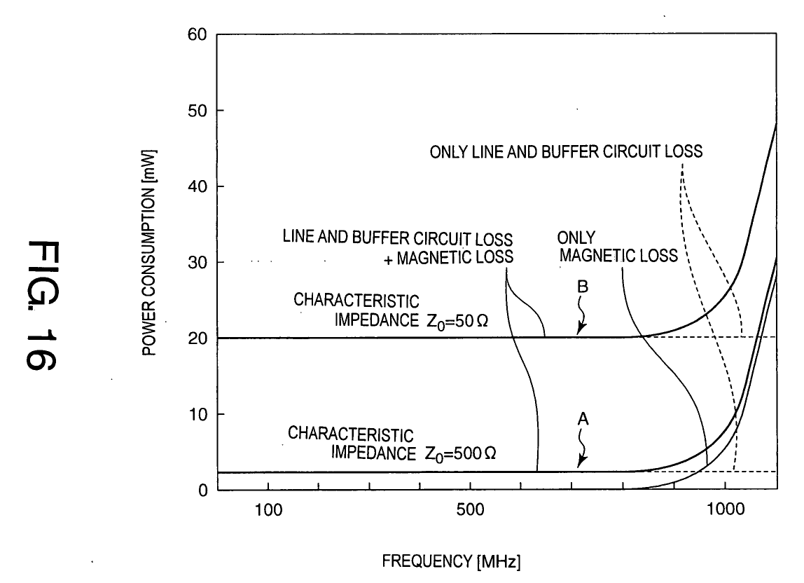

Among the wiring boards in Specific Example 1, the wiring board having a characteristic impedance of 500Ω was selected to thereby derive a relationship between the frequency and the power consumption, and the result thereof is shown in FIG. 16 by a curve A.

### Comparative Example 2

Among the wiring boards in Comparative Example 1, the wiring board having a characteristic impedance of 50Ω was selected to thereby derive a relationship between the frequency and the power consumption, and the result thereof is shown in FIG. 16 by a curve B.

### Evaluation 2

As shown in FIG. 16, although loss of the magnetic substance starts to increase from around the point exceeding 1 GHz because of approaching the rotation magnetization resonance frequency, the domain wall motion is stopped at frequencies smaller than about 1 GHz because of a single domain structure in the form of the fine magnetic substance and therefore low loss can be realized. It has been confirmed that, by forming transmission lines in the first insulator of Specific Example 3 adjusted to the relative permeability of 25 and setting the characteristic impedance to 500Ω, it is possible to achieve reduction in power consumption to 1/10 as compared with the characteristic impedance of 50Ω of Comparative Example 2 which is the conventional example.

Further, it has been confirmed that, as compared with the case of the impedance of 50Ω that has conventionally been used in general, the characteristic impedance of about 500Ω or more can be easily achieved in Specific Example 3 and therefore the current flowing in the lines can be reduced to about 1/10 or less so that the power consumption in the printed wiring board or a buffer circuit driving the lines becomes 1/10 or less.

In the foregoing specific examples, the present invention is applied to the printed wiring board. However, the present invention may also be applied to internal wiring of an LSI circuit, and a similar effect can be achieved.

(B) Now, multilayer circuit boards using a magneto-dielectric, according to embodiments of the present invention will be described with reference to the drawings.

### First Embodiment (Multilayer Circuit Board)

A multilayer circuit board using a magneto-dielectric, according to a first embodiment of the present invention is produced in the following manner.

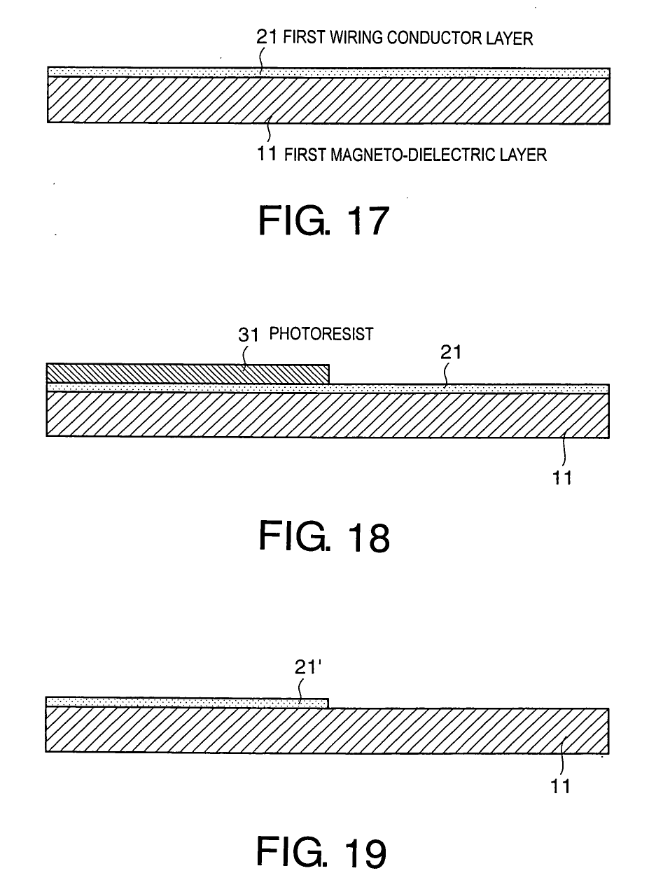

1) As shown in FIG. 17, copper plating was applied, by an electroless plating method, to a first magneto-dielectric (relative permeability μr=25, relative permittivity εr=2) 11 having a thickness of 50 μm to thereby form a first wiring conductor layer 21 having a thickness of 10 μm.

2) Then, as shown in FIG. 18, a photoresist 31 was applied to the first wiring conductor layer 21 and exposed by the use of a mask aligner, then, by developing it using a predetermined development liquid, openings were formed in the photoresist 31 at portions where no line would be formed.

3) Then, as shown in FIG. 19, copper of the first wiring conductor layer 21 exposed through the openings of the photoresist 31 was etched by the use of a cupric chloride solution to thereby form a first wiring layer pattern 21′. Thereafter, the photoresist was stripped by a resist stripping liquid.

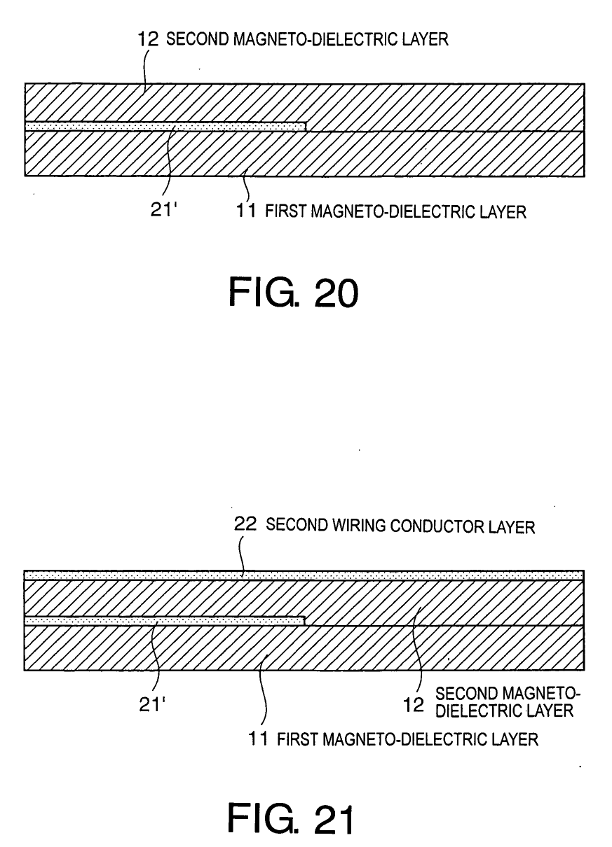

4) Then, as shown in FIG. 20, a second magneto-dielectric layer 12 (relative permeability μr=25, relative permittivity εr=2) was formed as an insulator layer by a vacuum press method so as to cover the first wiring layer pattern 21′.

5) Then, as shown in FIG. 21, copper plating was applied to the second magneto-dielectric layer 12 by the electroless plating method to form a second wiring conductor layer 22 having a thickness of 10 μm.

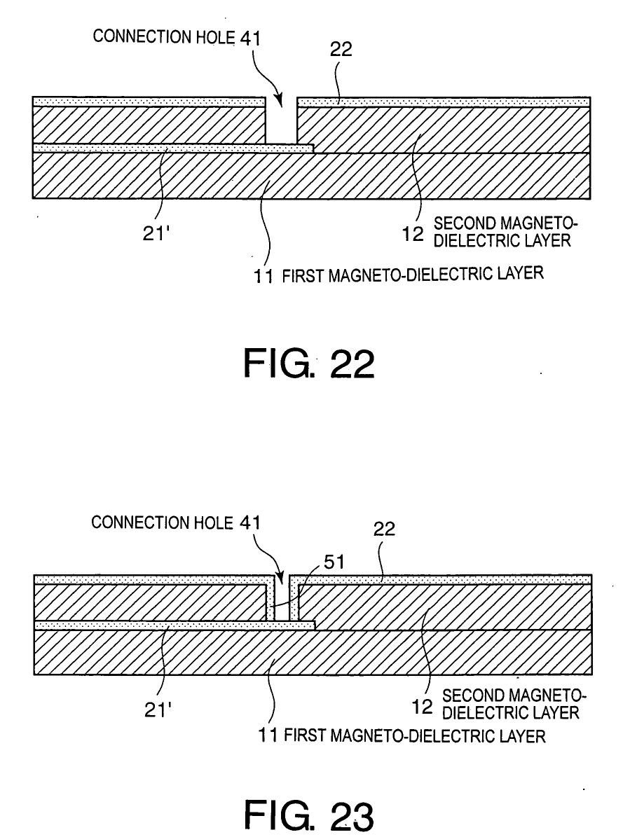

6) Then, as shown in FIG. 22, a connection hole 41 to be used for connection between the first wiring layer pattern 21′ and the second wiring conductor layer 22 was formed by a carbon dioxide laser beam.

7) In FIG. 22, a board was immersed into an ozone-containing acid pure liquid adjusted to pH 4 to 5 by putting 5 mg/L of O₃ into deaerated pure water and further adding CO₂ thereinto and ultrasonic cleaning was carried out using an ultrasonic wave of 1 MHz for fully cleaning the inside of the connection hole 41. Thereafter, using hydrogen-containing alkaline pure water adjusted to pH 9 to 10 by putting 1.3 mg/L of H₂ into deaerated pure water and further adding NH₃ thereinto, ultrasonic cleaning was carried out by the use of an ultrasonic wave of 1 MHz. Although depending on a contamination state, the cleaning temperature may be a room temperature and the cleaning time may be about 1 minute to 10 minutes. The cleaning process may be carried out repeatedly. Consequently, the magnetic substance residue remaining inside the connection hole 41 in the foregoing carbon dioxide laser processing was fully removed.

8) Then, as shown in FIG. 23, a copper plating film 51 was formed in the connection hole 41 by the electroless plating method to establish electrical connection between the first wiring layer pattern 21′ and the second wiring conductor layer 22.

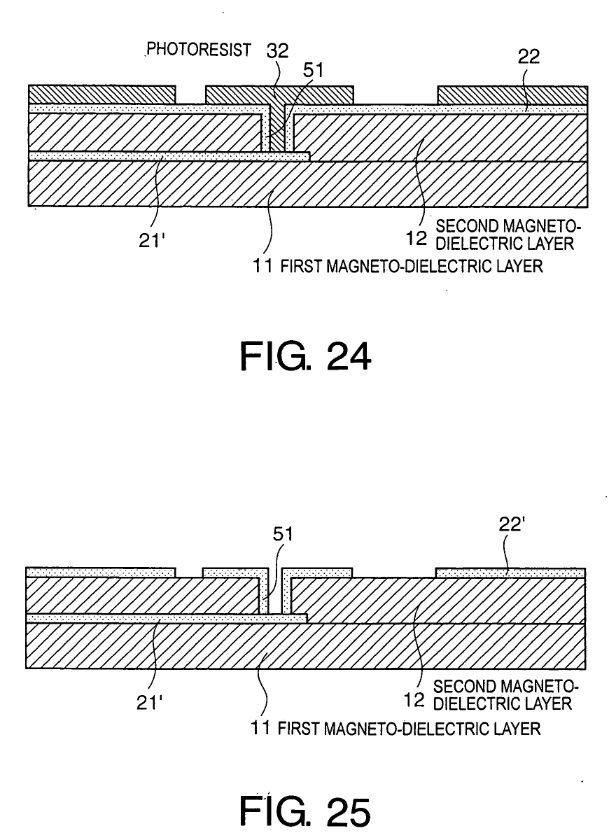

9) Then, as shown in FIG. 24, a photoresist 32 was applied, exposed, and developed to thereby form openings in the photoresist 32. Subsequently, as shown in FIG. 25, by etching the second wiring conductor layer 22 exposed through the openings of the photoresist 32 by the use of a cupric chloride solution, the second wiring conductor layer 22 was patterned into a desired pattern to thereby form a second wiring layer pattern 22′. Thereafter, the photoresist 32 was stripped.

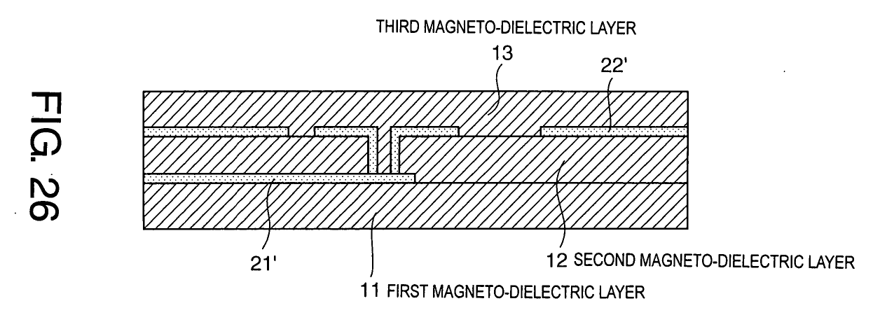

10) Then, as shown in FIG. 26, a third magneto-dielectric layer 13 (relative permeability μr=25, relative permittivity εr=2) was formed as an insulator layer by the vacuum press method so as to cover the second wiring layer pattern 22′.

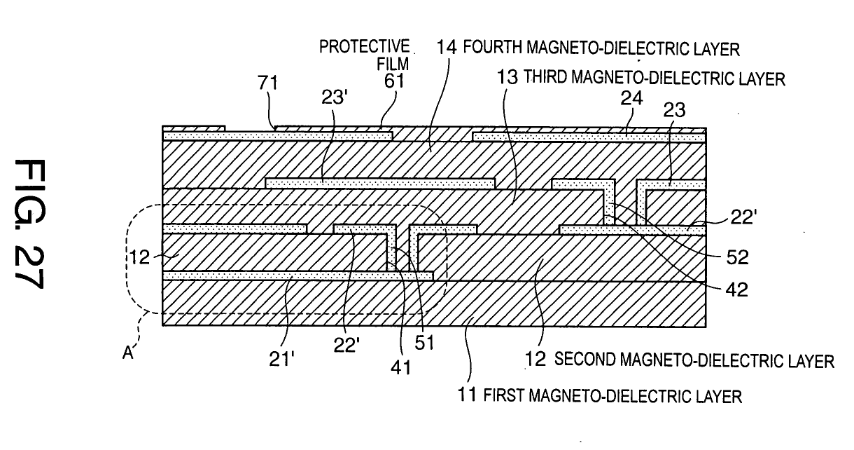

11) Then, as shown in FIG. 27, a plating layer made of copper was formed to 10 μm on the third magneto-dielectric layer 13 as a third wiring conductor layer 23 by the use of the electroless plating method.

12) Then, in FIG. 27, a connection hole 42 to be used for connection between the second wiring layer pattern 22′ and the third wiring conductor layer 23 was formed by a carbon dioxide laser beam.

13) In FIG. 27, a board was immersed into an ozone-containing acid pure water liquid adjusted to pH 4 to 5 by putting 5 mg/L of O₃ into deaerated pure water and further adding CO₂ thereinto and ultrasonic cleaning was carried out using an ultrasonic wave of 1 MHz for fully cleaning the inside of the connection hole 42. Thereafter, using hydrogen-containing alkaline pure water adjusted to pH 9 to 10 by putting 1.3 mg/L of H₂ into deaerated pure water and further adding NH₃ thereinto, ultrasonic cleaning was carried out by the use of an ultrasonic wave of 1 MHz. Consequently, the magnetic substance residue remaining inside the connection hole 42 in the foregoing carbon dioxide laser processing was fully removed.

14) Then, in FIG. 27, copper plating 52 was applied to the inside of the connection hole 42 by the electroless plating method to establish electrical connection between the second wiring layer pattern 22′ and the third wiring conductor layer 23.

15) Then, in FIG. 27, like in FIGS. 24 and 25, the third wiring conductor layer 23 was patterned to thereby form a third wiring layer pattern 23′.

16) Then, in FIG. 27, like in FIG. 26, a fourth magneto-dielectric layer 14 (relative permeability μr=25, relative permittivity εr=2) was formed as an insulator layer by the vacuum press method so as to cover the third wiring layer pattern 23′.

17) Then, in FIG. 27, a plating layer made of copper was formed to 10 μm on the fourth magneto-dielectric layer 14 as a fourth wiring conductor layer 24 by the use of the electroless plating method. Subsequently, like in FIGS. 24 and 25, the fourth wiring conductor layer 24 was patterned to thereby form a fourth wiring layer pattern 24′.

18) Finally, a photosensitive protective film 61 was applied and an opening 71 was formed at a component mounting portion of the protective film 61 by exposing, developing, and removing the component mounting portion of the protective film 61, thereby completing a circuit board shown in FIG. 27.

In FIG. 27, paying attention to a portion A including the second magneto-dielectric layer 12, it can be said that the circuit board is characterized by comprising, at the portion A, the insulator layer 12 having mutually opposing first and second main surfaces, and the first and second wiring layers 21′ and 22′ formed on the first and second main surfaces of the insulator layer 12, wherein the insulator layer 12 satisfies εr≦μr given that the relative permittivity of the insulator layer 22 is εr and the relative permeability thereof is μr. Herein, even if the whole of the insulator layer 12 does not satisfy εr≦μr, when at least a part of the insulator layer 12 satisfies εr≦μr, the power consumption reducing effect intended by the present invention can be achieved also in the multilayer circuit board. Further, since it is possible to reduce a leakage magnetic field from the line inside the magnetic body satisfying εr≦μr to the insulator not satisfying εr≦μr, crosstalk between the lines can be reduced.

At the foregoing portion A, the insulator layer 12 has the hole 41 perpendicular to the foregoing first and second main surfaces. The circuit board further comprises the electrical connection member 51 formed on the inner surface of the hole 41 in the state of contacting the foregoing first and second wiring layers 21′ and 22′ for electrically connecting the foregoing first and second wiring layers 21′ and 22′ together.

### Second Embodiment (Multilayer Circuit Board)

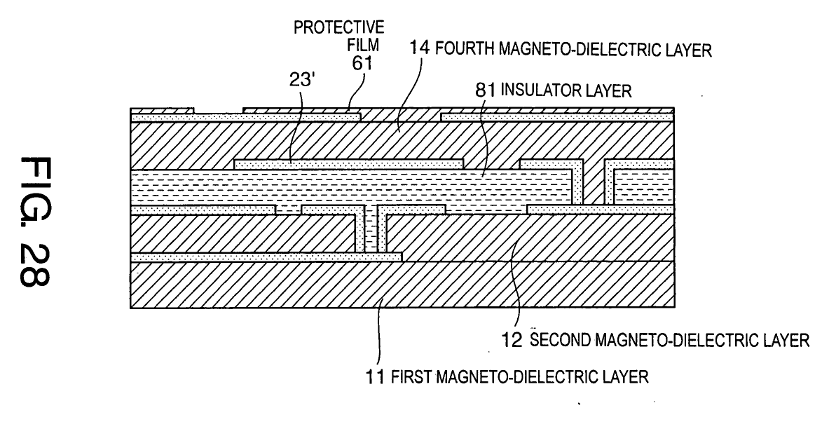

Referring to FIG. 28, there is shown a multilayer circuit board using a magneto-dielectric, according to a second embodiment of the present invention. This multilayer circuit board is formed with an insulator layer 81 instead of the third magneto-dielectric layer 13 in the multilayer circuit board of FIG. 27. The insulator layer 81 does not satisfy εr≦μr given that the relative permittivity of the insulator layer 81 is εr and the relative permeability thereof is μr.

In this manner, even if the insulator layer 81 is not a magneto-dielectric layer, a similar effect can be achieved.

### Third Embodiment (Multilayer Circuit Board)

Now, description will be given about a multilayer circuit board using a magneto-dielectric, according to a third embodiment of the present invention.

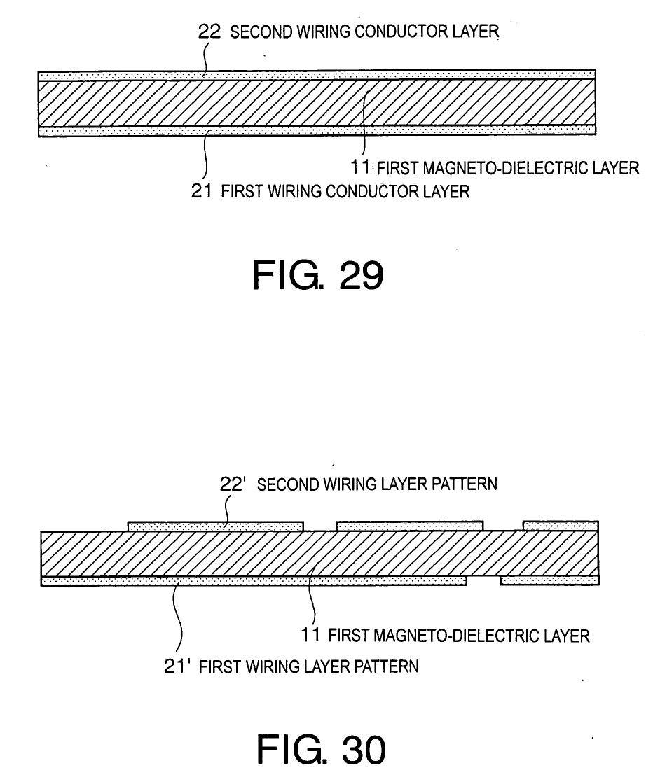

As shown in FIG. 29, first and second wiring conductor layers 21 and 22 like in the first embodiment were formed on mutually opposing first and second main surfaces of a first magneto-dielectric layer (relative permeability μr=25, relative permittivity εr=2) 11.

Then, as shown in FIG. 32, the first and second wiring conductor layers 21 and 22 were selectively etched like in the first embodiment so that first and second wiring layer patterns 21′ and 22′ were formed.

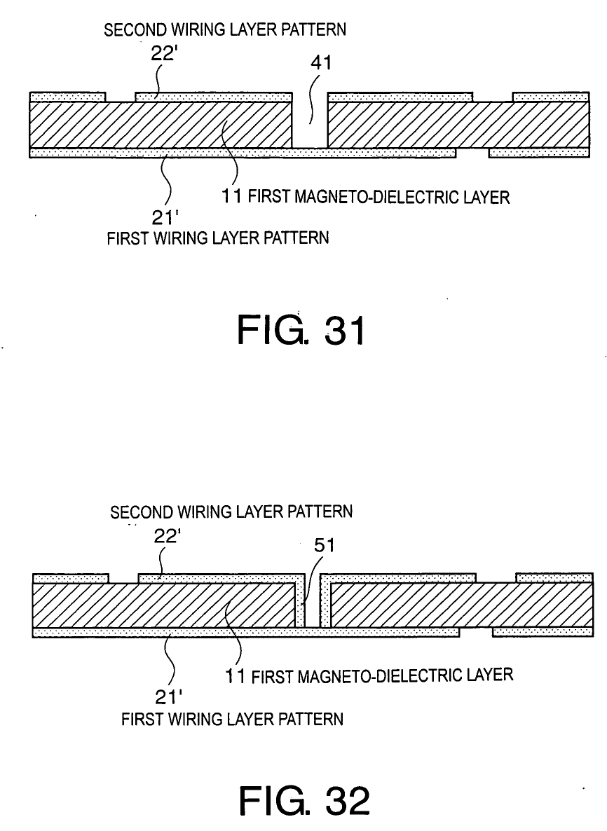

Then, as shown in FIG. 31, like in the description at the foregoing 6) of the first embodiment, a connection hole 41 to be used for connection between the first wiring layer pattern 21′ and the second wiring layer pattern 22′ was formed by a carbon dioxide laser beam.

Subsequently, in FIG. 31, like in the description at the foregoing 7) of the first embodiment, a board was immersed into an ozone-containing acid pure water liquid adjusted to pH 4 to 5 by putting 5 mg/L of O₃ into deaerated pure water and further adding CO₂ thereinto and ultrasonic cleaning was carried out using an ultrasonic wave of 1 MHz for fully cleaning the inside of the connection hole 41. Thereafter, using hydrogen-containing alkaline pure water adjusted to pH 9 to 10 by putting 1.3 mg/L of H₂ into deaerated pure water and further adding NH₃ thereinto, ultrasonic cleaning was carried out by the use of an ultrasonic wave of 1 MHz. Consequently, the magnetic substance residue remaining inside the connection hole 41 in the foregoing carbon dioxide laser processing was fully removed.

Then, as shown in FIG. 32, like in the description at the foregoing 8) of the first embodiment, copper plating 51 was applied to the inside of the connection hole 41 to establish electrical connection between the first wiring layer pattern 21′ and the second wiring layer pattern 22′.

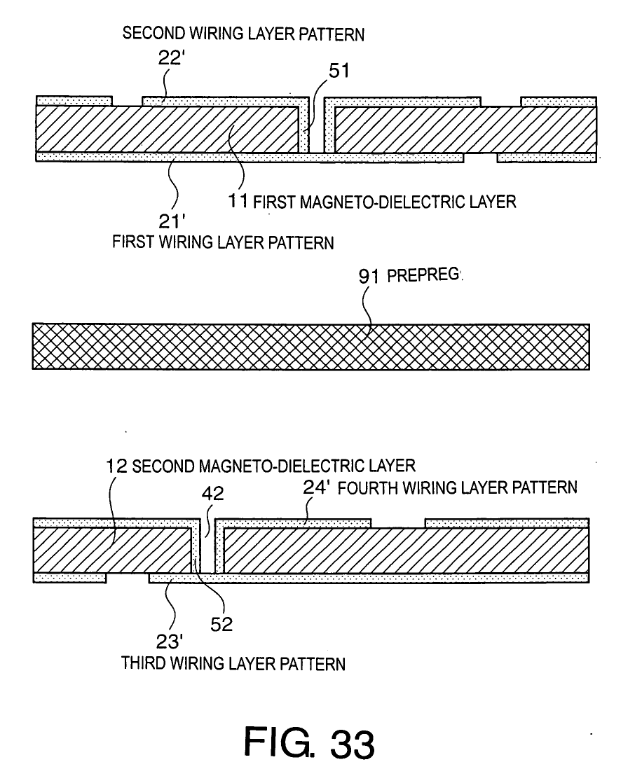

Then, as shown in FIG. 33, like in the description with respect to FIGS. 29 to 32, third and fourth wiring layer patterns 23′ and 24′ were formed on both main surfaces of a second magneto-dielectric layer (relative permeability μr=25, relative permittivity εr=2) 12. Then, copper plating 52 was applied to the inside of a connection hole 42 to establish electrical connection between the third wiring layer pattern 23′ and the fourth wiring layer pattern 24′.

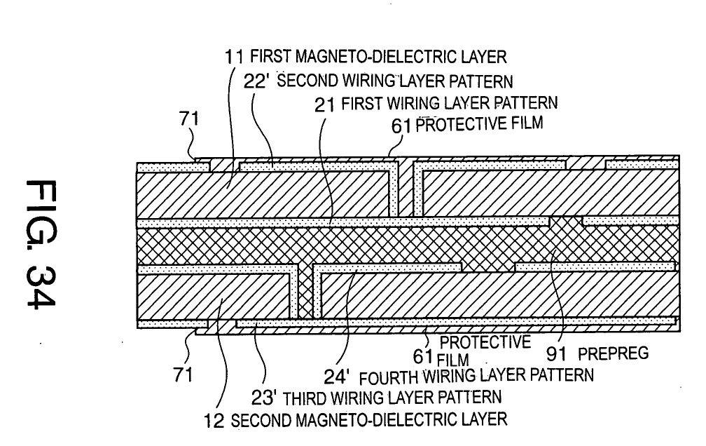

In FIG. 33, a plurality of composites each comprising the magneto-dielectric layer and the wiring layer patterns formed on both surfaces thereof were prepared and further a prepreg 91 was prepared, then, by heat pressing the plurality of composites each having the wiring layer patterns formed on both surfaces of the magneto-dielectric layer, via the prepreg 91, a multilayer circuit board as shown in FIG. 34 was obtained.

The prepreg 91 may be a magneto-dielectric or may not be the magneto-dielectric. In the case of the prepreg 91 being the magneto-dielectric, when the pressing is carried out while applying a magnetic field in the horizontal direction with respect to the plane of the board, orientation disturbance of the magnetic substance following melting of the prepreg is reduced so that dispersion of the permeability is reduced, and therefore, in-plane dispersion of the characteristic impedance given as Z=(μ/ε)^{1/2} is reduced, which is preferable.

In FIG. 34, photosensitive protective films 61 were applied to both surfaces of the multilayer circuit board, then, by exposing, developing, and removing connection hole forming portions of the protective films 61, openings 71 were formed at the connection hole forming portions.

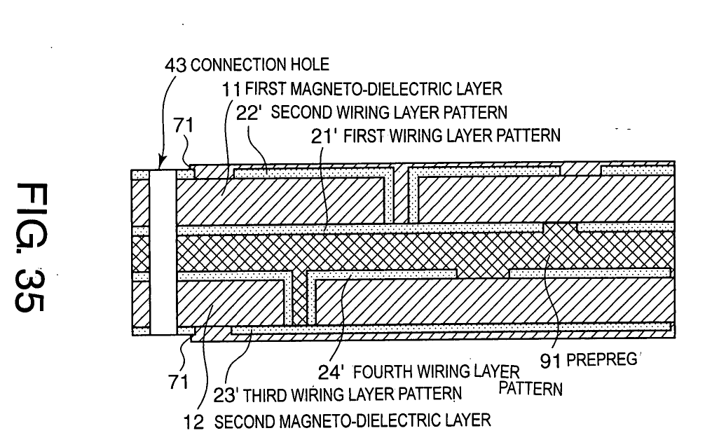

Subsequently, as shown in FIG. 35, a connection hole 43 was formed by the use of the technique as described in the foregoing 6) of the first embodiment, drilling, or the like, and the inside of the connection hole 43 was cleaned in the same manner as described in the foregoing 7) of the first embodiment.

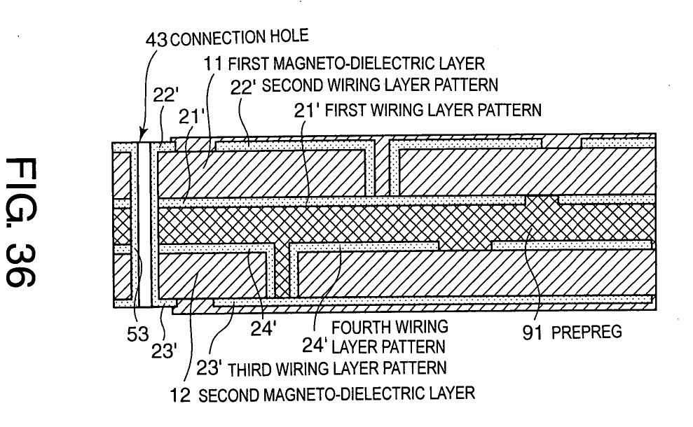

Finally, as shown in FIG. 36, like in the description at the foregoing 8) of the first embodiment, copper plating 53 was applied to the inside of the connection hole 43 to establish electrical connection among the first wiring layer pattern 21′, the second wiring layer pattern 22′, the third wiring layer pattern 23′, and the fourth wiring layer pattern 24′.

### Fourth Embodiment (Multilayer Circuit Board)

Now, description will be given about a multilayer circuit board using a magneto-dielectric, according to a fourth embodiment of the present invention.

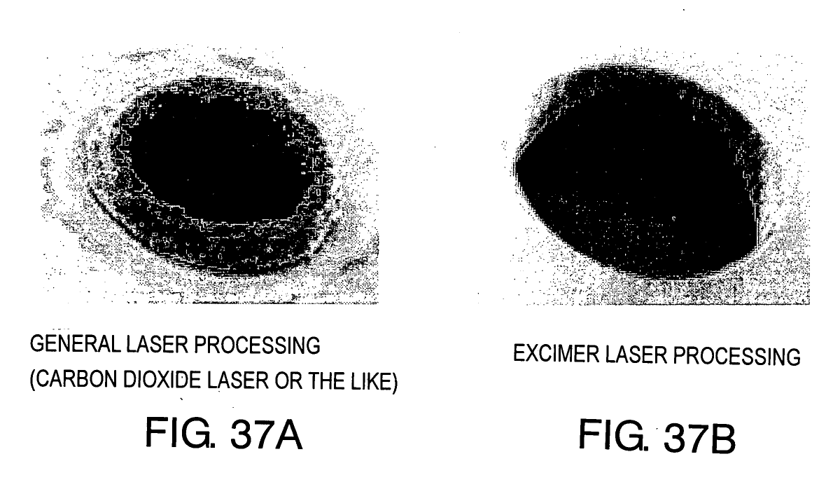

According to this fourth embodiment, an excimer light-emission pulse laser beam (laser beam with a wavelength of 193 nm or less) using ArF as an excitation medium was employed instead of the carbon dioxide laser when forming the connection hole 41 in FIG. 22 of the first embodiment, thereby forming a connection hole 41. As a result, an excellent opening as shown in FIG. 37B was obtained as the connection hole 41. Since the connection hole 41 is the excellent opening, the cleaning of the inside of the connection hole 41 as described in the foregoing 7) of the first embodiment is not required. A similar effect can be achieved by the use of a laser (wavelength: 355 nm) using the third harmonic of a Nd-YAG medium, instead of the excimer light-emission laser using ArF as the excitation medium.

On the other hand, when the connection hole 41 was formed using a carbon dioxide laser beam, the shape of an opening was extremely degraded as shown in FIG. 37A and thus an excellent opening was not obtained. When the wiring pattern is not elaborate so that influence of the shape of the opening is small, the formation of the opening may be carried out by the use of the carbon dioxide laser. Further, although depending on a use of the board, when a required magnetic substance amount is small, use may be made of an infrared laser of 700 nm or more such as the carbon dioxide laser, while, when the content of the magnetic substance is large, a short-wavelength laser of 400 nm or less is preferable. According to the study by the inventors, the short-wavelength laser is preferable when the content of the magnetic substance is approximately 20 volume % or more.

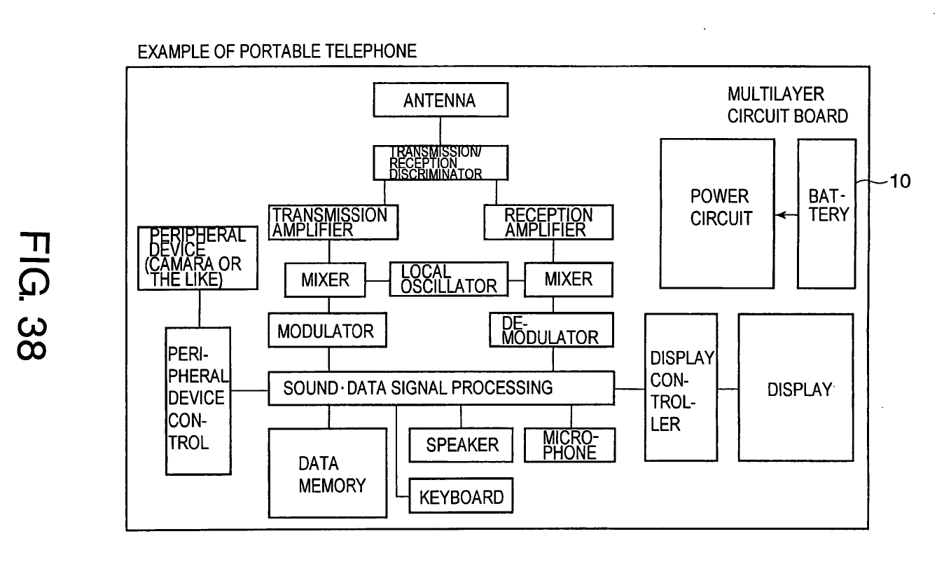

FIG. 38 shows a portable telephone as an electronic device having the multilayer circuit board obtained by any of the foregoing first to fourth embodiments. The portable telephone shown in FIG. 38 comprises a radio wave emission section including an antenna, a transmission/reception discriminator, a transmission amplifier, a mixer, a local oscillator, a modulator, and so forth.

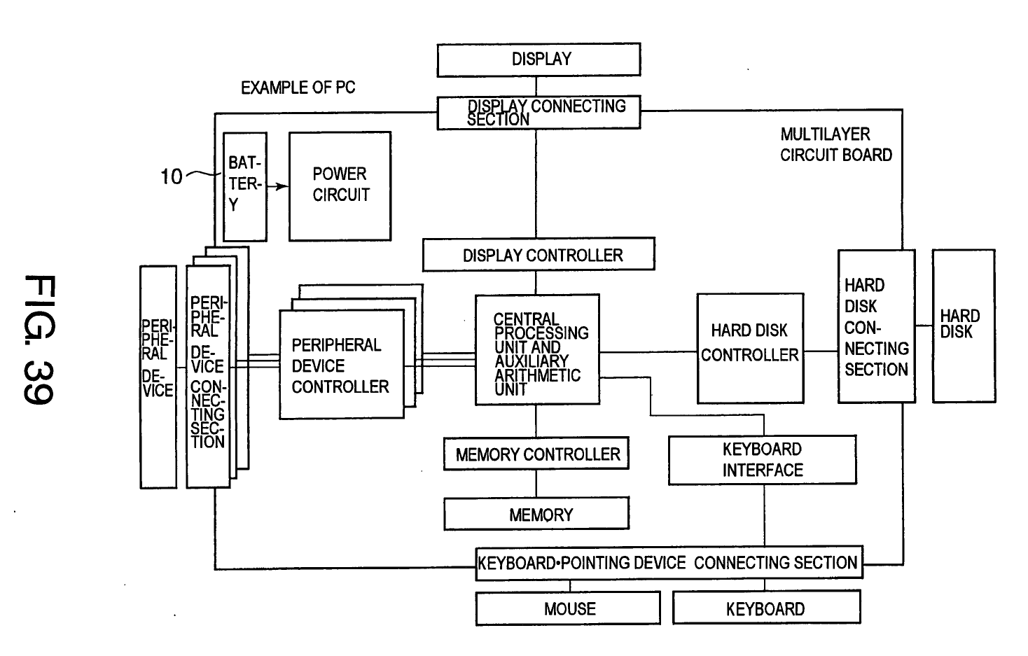

On the other hand, FIG. 39 shows a personal computer (PC) as an electronic device having the multilayer circuit board obtained by any of the foregoing first to fourth embodiments. The personal computer shown in FIG. 39 comprises a central processing unit (CPU) and an auxiliary arithmetic unit, and a memory as a storage section.

The portable telephone and the personal computer shown in FIGS. 38 and 39 each operate by receiving a power supply from a battery 10. Specifically, each of the portable telephone and the personal computer does not receive a power supply from a commercial power supply (external power supply), but receives a power supply from the battery 10 to operate.

In the multilayer circuit board obtained by any of the foregoing first to fourth embodiments, the magneto-dielectric being the insulator satisfying εr≦μr contains the magnetic powder dispersed in the insulator resin. The material of the magnetic powder may be powder of the insulating magnetic substance such as ferrite, or powder of a simple substance or an alloy of magnetic metal elements such as Fe, Ni, Co, and Cr.

Further, in the multilayer circuit board obtained by any of the foregoing first to fourth embodiments, it is not necessary to use the magneto-dielectric (insulator satisfying εr≦μr) at a layer or a portion, in the multilayer insulator layer, where a higher impedance is not required.

Further, the multilayer circuit board obtained by any of the foregoing first to fourth embodiments may also be used in an electronic device other than the portable telephone or the personal computer, for example, a server, a rooter, a television, a DVD (Digital Versatile Disc), a game machine, a monitor, a video camera, a digital camera, a projector, or the like.

Further, in the portable telephone as the electronic device shown in FIG. 38, any of the printed wiring boards described as [First Embodiment (Printed Wiring Board)], [Second Embodiment (Printed Wiring Board)], [Third Embodiment (Printed Wiring Board)], and [Fourth Embodiment (Printed Wiring Board)] may be used instead of the multilayer circuit board.

Likewise, in the personal computer as the electronic device shown in FIG. 39, any of the printed wiring boards described as [First Embodiment (Printed Wiring Board)], [Second Embodiment (Printed Wiring Board)], [Third Embodiment (Printed Wiring Board)], and [Fourth Embodiment (Printed Wiring Board)] may be used instead of the multilayer circuit board.

1. A circuit board having an insulator layer and a conductor buried inside said insulator layer, said circuit board characterized in that
said insulator layer comprises a first insulator satisfying a relationship of μr≧εr given that a relative permittivity is εr and a relative permeability is μr, and said conductor is substantially surrounded by said first insulator.

2. A circuit board according to claim 1, characterized in that
said insulator layer further comprises a second insulator not satisfying the relationship of μr≧εr, said conductor is substantially surrounded by said second insulator, and said second insulator is substantially surrounded by said first insulator.

3. A circuit board according to claim 1, characterized in that
said insulator layer further comprises a second insulator not satisfying the relationship of μr≧εr, a part of said conductor is substantially surrounded by said second insulator, and said second insulator and said conductor are substantially surrounded by said first insulator.

4. A circuit board according to claim 1, characterized in that
a predetermined number N (N is an integer equal to or greater than 2) of conductors are buried inside said insulator layer,
said predetermined number N of said conductors are substantially surrounded by a predetermined number N of first insulators, respectively, and
said predetermined number N of said first insulators are partitioned therebetween by second insulators not satisfying the relationship of μr≧εr.

5. A circuit board according to claim 1, characterized in that
said first insulator is formed by mixing a magnetic substance into an inorganic substance or an organic SOG.

6. A circuit board according to claim 5, characterized in that
said inorganic substance is an inorganic SOG, silica, alumina, aluminum nitride, silicon nitride, or ceramics.

7. A circuit board according to claim 5, characterized in that
said magnetic substance is an insulator, or a simple substance or an alloy of magnetic metal elements.

8. A circuit board according to claim 1, characterized in that
said first insulator contains a synthetic resin and a magnetic substance.

9. A circuit board according to claim 8, characterized in that
said synthetic resin is at least one resin selected from the group consisting of an epoxy resin, a phenol resin, a polyimide resin, a polyester resin, a fluorine resin, a denatured polyphenylether resin, a bismaleimide triazine resin, a denatured polyphenylene oxide resin, a silicon resin, a benzocyclobutene resin, a polyethylene naphthalate resin, a polycycloolefin resin, a polyolefin resin, a fluorocarbon polymer, a cyanate ester resin, a melamine resin, and an acrylic resin.

10. A circuit board according to claim 8, characterized in that
said magnetic substance is an insulator, or a simple substance or an alloy of magnetic metal elements.

11. An electronic device comprising the circuit board according to any of claims 1 to 10.

12. A circuit board characterized by comprising an insulator layer having opposing first and second main surfaces, and a first and a second wiring layer formed on said first and second main surfaces of said insulator layer, wherein at least a part of said insulator layer satisfies a relationship of εr≦μr given that a relative permittivity of said insulator layer is εr and a relative permeability thereof is μr.

13. An electronic device characterized by comprising a circuit board which comprises an insulator layer having opposing first and second main surfaces, and a first and a second wiring layer formed on said first and second main surfaces of said insulator layer, wherein at least a part of said insulator layer satisfies a relationship of εr≦μr given that a relative permittivity of said insulator layer is εr and a relative permeability thereof is μr.

14. An electronic device according to claim 13, characterized by comprising a battery and receiving a power supply from said battery to operate.

15. An electronic device according to claim 13, characterized by comprising a battery and being adapted to operate by receiving a power supply from said battery without receiving a power supply from an external power supply.

16. An electronic device according to any of claims 13 to 15, characterized by comprising radio wave emission means.

17. An electronic device according to any of claims 13 to 15, characterized by comprising an arithmetic processing section (CPU) and a storage section (memory).

18. A method of producing a circuit board comprising an insulator layer having a hole, wherein at least a part of said insulator layer satisfies a relationship of εr≦μr given that a relative permittivity of said insulator layer is εr and a relative permeability thereof is μr, said method characterized by comprising:
a step of performing ultrasonic cleaning of the inside of said hole by the use of ozone-containing acid pure water in which pH is adjusted to an acid region by adding O₃ and CO₂ into pure water; and
a step of performing ultrasonic cleaning by the use of hydrogen-containing alkaline pure water in which pH is adjusted to an alkaline region by adding H₂ and NH₃ into pure water.

19. A method of producing a circuit board comprising an insulator layer having a hole, wherein at least a part of said insulator layer satisfies a relationship of εr≦μr given that a relative permittivity of said insulator layer is εr and a relative permeability thereof is μr, said method characterized by comprising:
a step of forming said hole in said insulator layer by the use of a laser beam having a wavelength of 400 nm or less.

20. A method of producing a circuit board comprising an insulator layer having a hole, wherein at least a part of said insulator layer satisfies a relationship of εr≦μr given that a relative permittivity of said insulator layer is εr and a relative permeability thereof is μr, said method characterized by comprising:
a step of forming said hole in said insulator layer by the use of a laser beam of 700 nm or more.

21. A circuit board characterized by comprising an insulator layer having opposing first and second main surfaces and a hole connecting between said first and second main surfaces, and a first and a second wiring layer formed on said first and second main surfaces of said insulator layer, wherein at least a part of said insulator layer satisfies a relationship of εr≦μr given that a relative permittivity of said insulator layer is εr and a relative permeability thereof is μr, said circuit board further comprising an electrical connection member formed on an inner surface of said hole so as to contact said first and second wiring layers for electrically connecting between said first and second wiring layers.

22. A circuit board comprising a first insulator layer having opposing first and second main surfaces, a first and a second wiring layer formed on said first and second main surfaces of said first insulator layer, a second insulator layer formed on said second wiring layer, and a third wiring layer formed on a surface of said second insulator layer opposite to its side contacting said second wiring layer, wherein at least one of said first and second insulator layers is formed with a hole connecting the two or more layers optionally selected from said first to third wiring layers, said circuit board characterized in that at least a part of said first and second insulator layers satisfies a relationship of εr≦μr given that a relative permittivity of said first and second insulator layers is εr and a relative permeability thereof is μr, said circuit board further comprising an electrical connection member inside said hole for electrically connecting together the two or more layers optionally selected from said first to third wiring layers.

23. An electronic device characterized by comprising a circuit board which comprises an insulator layer having opposing first and second main surfaces and a hole connecting between said first and second main surfaces, and a first and a second wiring layer formed on said first and second main surfaces of said insulator layer, wherein at least a part of said insulator layer satisfies a relationship of εr≦μr given that a relative permittivity of said insulator layer is εr and a relative permeability thereof is μr, said circuit board further comprising an electrical connection member formed on an inner surface of said hole so as to contact said first and second wiring layers for electrically connecting between said first and second wiring layers.

24. An electronic device according to claim 23, characterized by comprising a battery and receiving a power supply from said battery to operate.

25. An electronic device according to claim 23, characterized by comprising a battery and being adapted to operate by receiving a power supply from said battery without receiving a power supply from an external power supply.

26. An electronic device according to any of claims 23 to 25, characterized by comprising radio wave emission means.

27. An electronic device according to any of claims 23 to 25, characterized by comprising an arithmetic processing section (CPU) and a storage section (memory).

28. An electronic device characterized by comprising a circuit board which comprises a first insulator layer having opposing first and second main surfaces, a first and a second wiring layer formed on said first and second main surfaces of said first insulator layer, a second insulator layer formed on said second wiring layer, and a third wiring layer formed on a surface of said second insulator layer opposite to its side contacting said second wiring layer, wherein at least one of said first and second insulator layers is formed with a hole connecting the two or more layers optionally selected from said first to third wiring layers, and at least a part of said first and second insulator layers satisfies a relationship of εr≦μr given that a relative permittivity of said first and second insulator layers is εr and a relative permeability thereof is μr, said circuit board further comprising an electrical connection member inside said hole for electrically connecting together the two or more layers optionally selected from said first to third wiring layers.

29. An electronic device according to claim 28, characterized by comprising a battery and receiving a power supply from said battery to operate.

30. An electronic device according to claim 28, characterized by comprising a battery and being adapted to operate by receiving a power supply from said battery without receiving a power supply from an external power supply.

31. An electronic device according to any of claims 28 to 30, characterized by comprising radio wave emission means.

32. An electronic device according to any of claims 28 to 30, characterized by comprising an arithmetic processing section (CPU) and a storage section (memory).

33. A circuit board characterized by comprising an insulator layer, wherein at least a part of said insulator layer satisfies a relationship of εr≦μr given that a relative permittivity of said insulator layer is εr and a relative permeability thereof is μr, said at least a part of said insulator layer is in the form of an insulator and a magnetic substance dispersed into said insulator, and a material of said magnetic substance is a simple substance or an alloy of magnetic metal elements.
